(19) United States
(12) Patent Application Publication
(10) Pub. No.: US 2003/0179277 A1
(43) Pub. Date: Sep. 25, 2003

(54) Use of a data carrier for storing micro-images

(76) Inventors: Stefan Stadler, Hamburg (DE); Jorn Leiber, Hamburg (DE)

Correspondence Address: NIXON & VANDERHYE, PC, 1100 N GLEBE ROAD, 8TH FLOOR, ARLINGTON, VA, 22201-4714, US

(21) Appl. No.: 10/344,164

(22) PCT Filed: Apr. 6, 2001
(86) PCT No.: PCT/EP01/04006

(30) Foreign Application Priority Data
Aug. 11, 2000 (DE) 100 39 374.8

(51) Int. Cl. G03F 7/20; G11B 7/24

(52) U.S. Cl. 347/224; 430/270.14; 430/320

(57) ABSTRACT

A data carrier (1) with a storage layer (2) which has a dye that can be changed by exposure to light is used for the storage of microimages by means of a write beam of a writing device.

The invention relates to the use of a data carrier for the storage of microimages.

Microimages contain image information which can be detected directly and without the use of encryption methods. For this purpose, a magnifying device is generally required. Information of different types can be stored in microimages, for example images in the narrower sense such as portraits, but also plans, drawings, text and so on. In a conventional way, microimages are produced photographically by an objective being used to record an image of the object to be stored on a photographic film, for example a high-resolution document film.

However, photographic methods of this type are relatively cumbersome to handle. For example, the film first has to be developed and then, if appropriate, recopied.

It is an object of the invention to provide a possible way of storing microimages which can be applied efficiently and flexibly.

This object is achieved by the use of a data carrier for the storage of microimages according to claim 1 and a method of putting a microimage into a data carrier according to claim 14. Advantageous refinements of the invention emerge from the subclaims.

According to the invention, use is made of a data carrier with a storage layer, which has a dye that can be changed by exposure to light, for the storage of microimages by means of a write beam from a writing device.

In a method for putting a microimage into a data carrier of this type, a write beam from a writing device, preferably a laser lithograph, is aimed at a storage layer of the data carrier and is driven in accordance with the two-dimensional microimage information contained in the microimage in such a way that the dye in the storage layer is changed locally in accordance with the two-dimensional microimage information.

As a result of specific local change in the dye in the storage layer, a real image can be produced, similar to that known from a black and white photograph. If the writing operation is carried out with the aid of a laser lithograph whose write beam sweeps over the storage layer in order to put the desired microimage information sequentially into the data carrier, a resolution of about 50 000 dpi (that is to say about 0.5 μm) may be achieved. Therefore, depending on the selected laser parameters (in particular exposure time, laser power and optical wavelength of the write beam) and the dye, points (pixels) of about 500 nm to 1 μm diameter can be written. If the write beam from a laser lithograph is guided over the storage layer of the data carrier in pulsed operation, typical pulse durations lie in the range from about 1 μsec to 10 μsec at a beam power of about 1 mW to 10 mW to put a point in. Accordingly, the images produced from these points can become very small, for example 128 μm×128 μm, and nevertheless still offer good resolution. Microimages of this type are preferably observed with a microscope. Other dimensions are likewise conceivable, however, for example 1 mm×1 mm; in this case, a magnifying glass would even be sufficient for viewing.

For the invention there are many possible applications. For example, a microimage can be a microportrait which, for example, is provided as an additional, difficult to forge, security feature in identity cards or the like. Likewise conceivable in this sector are microsignatures.

Another possibility is to apply instructions for components directly to the relevant component. For example, a PIN allocation or even a complete installation instruction or a circuit diagram can be applied directly to an integrated circuit (chip). Since instructions of this type are connected to the part to be processed or installed, the additional carrying of additional documents such as books, files, and so on is dispensed with.

The invention therefore permits microimages, which can be used in a flexible way, to be created quickly, efficiently and flexibly. As opposed to photographic methods, as a rule no chemical intermediate steps such as developing or fixing are required.

The dye of the storage layer of the data carrier can preferably be bleached out or destroyed, at least to some extent. In this case, the molecules of the dye can be bleached out or destroyed under exposure to the radiation of the write beam which is used to put microimage information into the storage layer. “Bleaching out” is understood to mean damaging the chromophoric system of a dye molecule as a result of excitation with intensive light of suitable wavelength, without destroying the basic framework of the dye molecule in the process. In this case, the dye molecule loses its coloured properties and, given adequate exposure, becomes optically transparent to the light used for bleaching. On the other hand, if the basic framework of a dye molecule is also destroyed, the change effected by the exposure is referred to as “destruction” of the dye. The light used for the exposure, that is to say to put the information in, does not have to lie in the visible wavelength range.

Dyes that can be bleached out easily are particularly suitable as the dye, such as azo and diazo dyes (for example the Sudan Red Family). For example, in the case of dyes from the Sudan Red Family, information can be put in with a write beam with an optical wavelength of 532 nm. However, dyes of this type are preferably not so unstable with respect to exposure that a bleaching process already begins as a result of ambient light (sun, artificial illumination). If the write beam is produced by a laser, considerably higher intensities can be achieved in the storage layer than in the case of exposure by ambient light, so that dyes are available which permit a storage layer that is at least largely insensitive with respect to ambient light. The dye therefore does not have to be sensitive to light, quite the opposite of a photographic film. If, on the other hand, the dye of the storage layer is not to be bleached out but destroyed with a higher laser power, recourse can be made to a large number of dyes. In this case, the absorption maximum of the respective dye is preferably matched to the wavelength of the laser used as the write beam. Further suitable dyes are polymethine dyes, arylmethine dyes and aza[18]annulene dyes.

Instead of dyes which can be bleached out or destroyed (or in addition to these), the use of photochromic materials is also possible, which change their colour when irradiated with light of suitable wavelength. This change is preferably irreversible. If the microimage information is to be deleted or overwritten, the photochromic material can also have a reversible system, however. Examples of photochromic materials are spirocompounds and inorganic metal complexes, which change their oxidation stage and therefore their colour under irradiation.

The data carrier preferably has a carrier for the storage layer. The carrier provided can be, for example, a polymer film, which can also be configured as a transparent polymer film. However, it is also conceivable to use a carrier which is flexurally rigid or not transparent. Metals or plastics, for example, are considered.

In a preferred refinement of the invention, the storage layer has a polymer matrix in which dye molecules are embedded. The dye molecules are preferably distributed homogeneously in the storage layer or part of the storage layer. Materials recommended for the polymer matrix are polymers or copolymers of high optical quality, such as polymethyl methacrylate (PMMA) or, even better, the more temperature-stable polyimides or polyetherimides or polymethylpentene. Other examples are polycarbonate or cycloolefinic copolymers. During the production of a data carrier, a polymer matrix which contains dye can be applied, for example by means of spin coating or by doctoring on, to a carrier or to a carrier previously provided with a reflective layer. Alternatively, printing techniques are also recommended to apply the dye to a carrier, the dye preferably likewise being embedded in a polymer matrix which serves as a binder.

In a preferred refinement of the invention, the data carrier has an adhesive layer for sticking the data carrier to an object. The adhesive layer makes it possible to stick the data carrier quickly and without difficulty to any desired object, for example to an integrated circuit (see above). Suitable as the adhesive layer are, in particular, a self-adhesive layer or a layer having a pressure-sensitive adhesive, which is preferably provided with a pull-off protective covering (for example of a film or a silicone paper) in the delivery state of the data carrier.

Apart from the layers previously mentioned, the data carrier can also have additional layers, for example a protective layer of a transparent varnish or polymer which is arranged in front of the storage layer. A reflective layer located behind the storage layer can also be advantageous which could make it easier to view the microimages put into the storage layer. An optional adhesive layer is preferably located behind the reflective layer or behind the mechanical carrier.

As already mentioned, a microimage can be put into the storage layer of the data carrier with the aid of the write beam from a laser lithograph. The writing speed and other details depend, inter alia, on the parameters of the write laser. (laser power, optical wavelength) and the exposure time and also on the dye and the properties of the storage layer. The local microimage information can be stored in a pixel in binary encoded form or in continuously encoded form. In the first case, a pixel can assume the two states “black” and “white”, while in the latter case all the grey stages lying in between are also possible. If different grey values can be assigned to a pixel, a particularly high storage density can be achieved. However, even in the first case, the impression of grey values can be implemented in that, for example, the number of “black” pixels within a darker zone within a microimage is greater than the number of the “white” pixels; however, this representational method reduces the physical resolving power.

In order to view a microimage, a microscope or at least a magnifying glass and suitable management of illumination are as a rule required.

In the following text, the invention will be explained in more detail using exemplary embodiments. In the drawings:

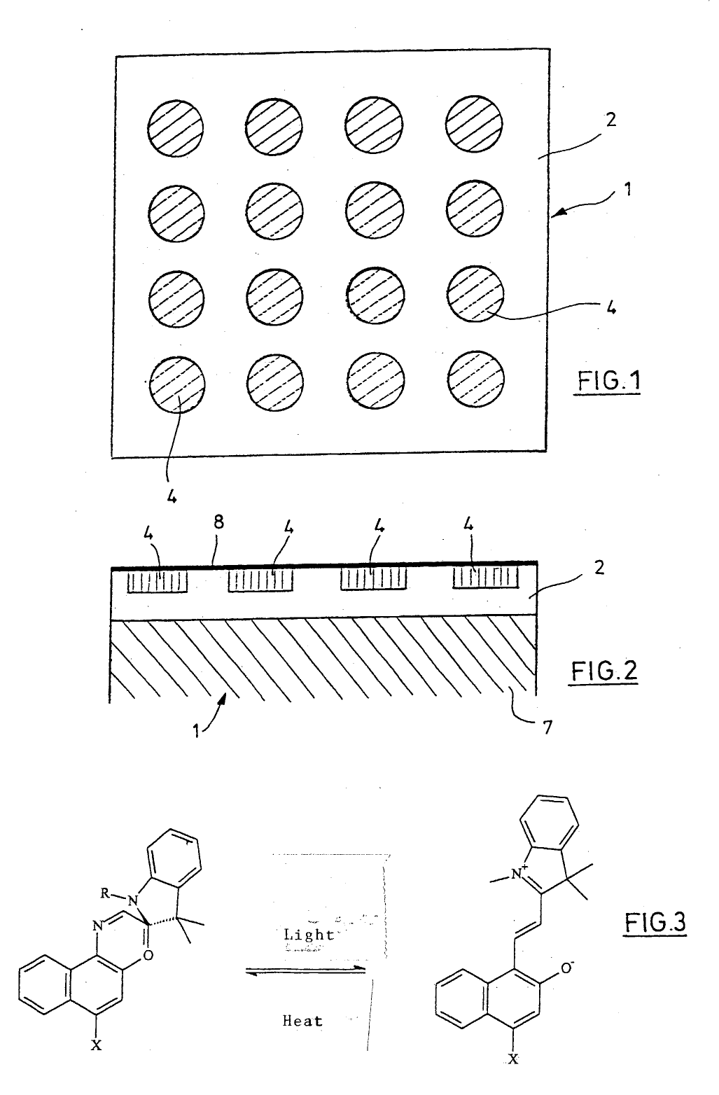

FIG. 1 shows a schematic plan view of a detail from a data carrier with input microimage information,

FIG. 2 shows a longitudinal section through the data carrier from FIG. 1, and

FIG. 3 shows a schematic representation of the action of a spirocompound as photochromic material.

FIG. 1 is a schematic plan view of one embodiment of a data carrier 1, into which information for a microimage is put.

The data carrier 1 has a polymer matrix which is set up as a storage layer 2 and in which the dye molecules are embedded. In the exemplary embodiment, the polymer matrix consists of polymethyl methacrylate (PMMA) and has a thickness of 1 μm. Other thicknesses are likewise possible. In the exemplary embodiment, the dye used is Sudan red in a concentration such that an optical density of 0.8 results over the thickness of the storage layer 2, if the dye in the storage layer 2 is not changed by exposure.

The optical density is a measure of the absorption, here based on the optical wavelength of a write beam. The optical density is defined as the negative decimal logarithm of the transmission through the storage layer 2, which agrees with the product of the extinction coefficient at the wavelength of the write beam used, the concentration of the dye in the storage layer 2 and the thickness of the storage layer 2. Preferred values for the optical density lie in the range from 0.2 to 1.0; other values are likewise conceivable, however.

In the data carrier 1, information is stored in the form of pixels 4. In the region of a pixel 4, the absorption capacity and the reflection behaviour of the storage layer 2 can be different from that in the zones between the pixels 4. In this case, the information can be stored in a pixel in binary encoded form, by the pixel assuming, for example, only the states “black” or “white”. However, it is more advantageous to store the information in a pixel 4 in continuously encoded form, it being possible for the pixel 4 also to assume all the grey values lying between two extreme states.

In the exemplary embodiment, a pixel 4 has a diameter of about 0.8 μm. Forms other than circular pixels 4 are likewise possible, for example square or rectangular pixels, but also other sizes. The typical dimension of a pixel is preferably about 0.5 μm to about 1.0 μm. FIG. 1 is therefore a much enlarged illustration and merely shows a detail from the data carrier 1. The interstices between the pixels 4 can also be relatively smaller or larger than shown in FIG. 1.

FIG. 2 shows a detail from the data carrier 1 in a schematic longitudinal section, specifically not to scale. It can be seen that, in the exemplary embodiment, a pixel 4 does not extend over the full thickness of the storage layer 2. In practice, on the basis of the writing operation for putting information in, in which the dye in the storage layer 2 is changed in the region of a pixel 4 with the aid of a focused write beam, the transition zone in the lower region of a pixel 4 to the lower region of the storage layer 2 is continuous, that is to say the absorption capacity changes gradually in this zone and is not delimited as sharply as illustrated in FIG. 2. This is similarly true of the lateral edges of a pixel 4.

The storage layer 2 is applied to a mechanical carrier 7 which, in the exemplary embodiment, consists of a polymer film of biaxially oriented polypropylene of 50 μm thickness. Other dimensions and materials for a polymer film, but also carriers which are flexurally rigid are likewise possible. However, it is also conceivable to design the storage layer 2 to be self-supporting. In the exemplary embodiment, a protective layer 8 is applied to the upper side of the storage layer 2.

In the exemplary embodiment, to produce the data carrier 1, first of all the polymer matrix with the dye of the storage layer 2 is doctored onto the carrier 7 and then the protective layer 8 is applied. As an option, a self-adhesive layer, not illustrated in the figures, can also be arranged under the carrier 7.

In order to put-a microimage into the data carrier 1, the write beam from a laser lithograph is used in the exemplary embodiment, having a resolution of about 50000 dpi (that is to say about 0.5 μm). The write beam from the laser lithograph is guided over the storage layer 2 of the data carrier 1 in pulsed operation (typical pulse duration of about 1 μsec to 10 μsec at a beam power of about 1 mW to 10 mW to put a pixel 4 in), in order to put the desired two-dimensional microimage information sequentially into the data carrier 1 (or a preselected region of the data carrier 1). In the process, the write beam changes the dye in the storage layer 2 locally in accordance with the two-dimensional microimage information and in this way produces the pixels 4, as explained above. The Sudan red dye used in the exemplary embodiment is in this case bleached out in accordance with the desired grey value.

In order to detect or to read a microimage stored in the data carrier 1 in this way, a magnifying device is required, for example a microscope or a magnifying glass. The light used for the illumination beam path of the magnifying device generally has a substantially weaker intensity than the write beam from the laser lithograph. The dye in the storage layer 2, and therefore the stored microimage information, is therefore not changed or changed only insignificantly during the reading or viewing operation.

The states of a photochromic spirocompound are illustrated schematically in FIG. 3. A spirocompound of this type can be used as a dye in the storage layer of the data carrier.

In spirocompounds, the planarity of the π electron system is interrupted by a ring closure, for which reason the molecules exhibit short-wave absorption bands. As a result of irradiation by light (preferably in the ultraviolet or blue), a bond is broken and the ring is therefore separated and an extended π electron system is produced, which absorbs in the visible. The position of the absorption maximum depends on the length of the π-conjugated system and the type of residue X.

Conversely, by heating the π electron system, renewed formation of the bond is made possible, so that the configuration with short-wave absorption bands shown in the left-hand part of FIG. 3 is produced again. This opens up the possibility, in the case of a data carrier whose storage layer has such a reversible system as the dye, of erasing the input microimage information and, if appropriate, rewriting it.

1. Use of a data carrier (1) with a storage layer (2) which has a dye that can be changed by exposure to light for the storage of microimages by means of a write beam of a writing device.

2. Use according to claim 1, characterized in that the dye can be bleached out or destroyed, at least to some extent.

3. Use according to claim 2, characterized in that the dye has at least one of the dyes selected from the following group: azo dyes, diazo dyes, polymethine dyes, arylmethine dyes, aza[18]annulene dyes.

4. Use according to one of claims 1 to 3, characterized in that the dye has a photochromic material.

5. Use according to claim 4, characterized in that the photochromic material has at least one of the materials selected from the following group: spirocompounds, inorganic metal complexes.

6. Use according to claim 4 or 5, characterized in that the photochromic material has a reversible system.

7. Use according to one of claims 1 to 6, characterized in that the data carrier (1) has a carrier (7) for the storage layer (2).

8. Use according to claim 7, characterized in that the carrier (7) has a polymer film.

9. Use according to one of claims 1 to 8, characterized in that the storage layer (2) has a polymer matrix in which dye molecules are embedded.

10. Use according to claim 9, characterized in that the polymer matrix has at least one of the polymers or copolymers selected from the following group: polymethyl methacrylate, polyimide, polyetherimide, polymethylpentene, polycarbonate, cycloolefinic copolymer.

11. Use according to one of claims 1 to 10, characterized in that the data carrier (1) has an adhesive layer for sticking the data carrier (1) to an object.

12. Use according to one of claims 1 to 11, characterized in that at least one microimage is stored on the data carrier (1).

13. Use according to one of claims 1 to 12, characterized in that the data carrier (1) is set up for the storage of at least one of the microimages selected from the following group: microportraits, microsignatures, instructions for components.

14. Method of putting a microimage into a data carrier which has the features according to one of claims 1 to 13, wherein a write beam of a writing device, preferably a laser lithograph, is aimed at a storage layer (2) of the data carrier (1) and is driven in accordance with the two-dimensional microimage information contained in the microimage in such a way that the dye in the storage layer (2) is changed locally in accordance with the two-dimensional microimage information.

15. Method according to claim 14, characterized in that the two-dimensional microimage information is put into the storage layer in the form of pixels (4) of predefined size, preferably in the range from 500 nm to 1 μm.

16. Method according to claim 15, characterized in that the local microimage information is stored in a pixel in binary encoded form.

17. Method according to claim 15, characterized in that the local microimage information is stored in a pixel (4) in continuously encoded form.
